(19) United States
(12) Patent Application Publication
(10) Pub. No.: US 2025/0275250 A1
(43) Pub. Date: Aug. 28, 2025

(54) STAGGERED THREE-DIMENSIONAL CHIP STACKING

(71) Applicant: International Business Machines Corporation, Armonk, NY (US)

(72) Inventors: Rajiv Joshi, Yorktown Heights, NY (US); Craig R. Walters, Highland, NY (US); Christopher Joseph Berry, Red Hook, NY (US); Alper Buyuktosunoglu, White Plains, NY (US)

(21) Appl. No.: 18/588,760

(22) Filed: Feb. 27, 2024

(51) Int. Cl. H01L 27/06; H01L 23/367; H01L 23/528; H01L 25/065

(52) U.S. Cl. CPC H10D 88/00; H01L 23/367; H01L 23/528; H01L 25/0657; H01L 2225/06527; H01L 2225/06541; H01L 2225/06589

(57) ABSTRACT

A 3D chip stack is provided including a first chip (including core units, cache units and power elements) and a second chip (including core units, cache units and heat spreader elements) that are stacked one on top of the other in a staggered manner and a power via is present that connects one of the power elements of the first chip to one of the core units of the second chip, and a thermal via is present that connects one of the core units of the first chip to one of the heat spreader elements of the second chip.

### BACKGROUND

The present application relates to semiconductor technology, and more particularly to a three-dimensional (3D) chip stack structure including a first chip and a second chip that are stacked in a staggered manner.

3D chip stacking is a technique used to manufacture MOS (metal-oxide semiconductor) integrated circuits (ICs) by stacking a plurality of ICs and interconnecting them vertically using, for instance, through-silicon vias (TSVs) or Cu—Cu connections. This technique allows the ICs to behave as a single device, which can lead to performance improvements at reduced power and a smaller footprint than conventional two-dimensional processes.

### SUMMARY

A 3D chip stack is provided including a first chip (including core units, cache units and power elements) and a second chip (including core units, cache units and heat spreader elements) that are stacked one on top of the other in a staggered manner and a power via is present that connects one of the power elements of the first chip to one of the core units of the second chip, and a thermal via is present that connects one of the core units of the first chip to one of the heat spreader elements of the second chip.

In one embodiment of the present application, the 3D chip stack includes a first chip including a first number of core units and a first number of cache units, and having power elements located between each neighboring core unit of the first chip. The 3D chip stack also includes a second chip including a second number of core units and a second number of cache units, and having a heat spreader element located on at least one of the core units of the second chip. In the present application, the first chip and the second chip are stacked one on top of the other in a staggered manner. The 3D chip stack of the present application further includes a power via connecting one of the power elements of the first chip to one of the core units of the second chip, and a thermal via connecting one of the core units of the first chip to one of the heat spreader elements of the second chip. In the 3D chip stack, the heat spreader element is placed with reference to thermal spots on the first chip and connected to a bottom surface where the thermal spot are prominent by the thermal vias.

In another embodiment of the present application, the 3D chip stack includes a first chip including a first number of core units and a first number of cache units, and having power elements located between each neighboring core unit of the first chip. The 3D chip stack also includes a second chip including a second number of core units and a second number of cache units, and having a heat spreader element located on at least one of the core units of the second chip. In the present application, the first chip and the second chip are stacked one on top of the other in a staggered manner, and the core units of the first chip are located on the periphery of the first chip, and the core units of the second chip are located on the periphery of the second chip. The 3D chip stack of this embodiment of the present application further includes a power via connecting one of the power elements of the first chip to one of the core units of the second chip, and a thermal via connecting one of the core units of the first chip to one of the heat spreader elements of the second chip. In the 3D chip stack, the heat spreader element is placed with reference to thermal spots on the first chip and connected to a bottom surface where the thermal spot are prominent by the thermal vias.

### BRIEF DESCRIPTION OF THE DRAWINGS

FIG. 1 is an illustration of a first chip that can be employed in accordance with an embodiment of the present application.

FIG. 2 is an illustration of a second chip that can be employed in accordance with an embodiment of the present application.

FIG. 3 is an illustration showing a 3D chip stack structure in which the second chip of FIG. 2 is stacked in a staggered manner over the first chip of FIG. 1.

FIG. 4 is an illustration showing a 3D chip stack structure in which the second chip of FIG. 2 is stacked in a staggered manner over the first chip of FIG. 1 and including power vias and thermal vias.

### DETAILED DESCRIPTION

The present application will now be described in greater detail by referring to the following discussion and drawings that accompany the present application. It is noted that the drawings of the present application are provided for illustrative purposes only and, as such, the drawings are not drawn to scale. It is also noted that like and corresponding elements are referred to by like reference numerals.

In the following description, numerous specific details are set forth, such as particular structures, components, materials, dimensions, processing steps and techniques, in order to provide an understanding of the various embodiments of the present application. However, it will be appreciated by one of ordinary skill in the art that the various embodiments of the present application may be practiced without these specific details. In other instances, well-known structures or processing steps have not been described in detail in order to avoid obscuring the present application.

It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “beneath” or “under” another element, it can be directly beneath or under the other element, or intervening elements may be present. In contrast, when an element is referred to as being “directly beneath” or “directly under” another element, there are no intervening elements present.

The terms substantially, substantially similar, about, or any other term denoting functionally equivalent similarities refer to instances in which the difference in length, height, or orientation conveys no practical difference between the definite recitation (e.g., the phrase sans the substantially similar term), and the substantially similar variations. In one embodiment, substantial (and its derivatives) denote a difference by a generally accepted engineering or manufacturing tolerance for similar devices, up to, for example, 10% deviation in value or 10° deviation in angle.

As mentioned above, 3D chip stacking is used in the semiconductor industry to manufacture MOS ICs by stacking a plurality of ICs one atop the other and thereafter interconnecting them vertically. Existing 3D chip stacking techniques focus on consistent monolithic unit over unit solutions. For example, in conventional 3D chip stacking cache units are stacked over cache units, and logic units are stacked over logic units. Also, and in existing 3D chip stacking techniques, 3D thermal solution focus on restricting units on an all-or-nothing basis. That is, upper hot units are not stacked over lower hot units. Further, and in existing 3D chip stacking techniques TSV solutions focus on an all or nothing solution. An integrated approach to optimize these elements across 3D layers is lacking in the semiconductor industry.

A 3D chip stack (see, for example, FIG. 4) is provided including a first chip (including core units, cache units and power elements) and a second chip (including core units, cache units and heat spreader elements) that are stacked one on top of the other in a staggered manner and a power via is present that connects one of the power elements of the first chip to one of the core units of the second chip, and a thermal via is present that connects one of the core units of the first chip to one of the heat spreader elements of the second chip. The staggered orientation of the first chip and the second chip reduces and confines power/thermal management points.

Throughout the present application, the term “core unit” denotes a microprocessor that carriers out programs and multiple other actions on a computer. The core unit can contain a plurality of transistors including logic transistors, as well as device circuitry including I/O circuitry.

Throughout the present application, the term “cache unit” denotes a smaller, faster memory unit, which is located closer to the core unit than a computer's main memory. The cache can store copies of the data from frequently used main memory locations.

Throughout the present application, the term “power element” denotes a power rail that delivers power to adjacent core units of the first chip and one of the core units of the second chip. In some embodiments, the power element is composed of an electrically conductive power rail material (refractory or high conductivity) including, but not limited to, tungsten (W), cobalt (Co), ruthenium (Ru), copper (Cu), platinum (Pt), rhodium (Rh), or palladium (Pd).

Throughout the present application, the term “heat spreader element” denotes a component that increases the heat flow away from a hot device/area such as, for example, one of the core units of the second chip. The heat spreader element is composed of a thermally conductive material such as, for example, silicon (Si), Cu or diamond-like carbon (DLC). In the present application, the heat spreader element is positioned on each end of the core units of the second chip.

Throughout the present application, the term “power via” denotes a via that is used in the present application to deliver power from the power element present in the first chip to one of the core units that is present in the second chip. In some embodiments, the power via can be composed of an electrically conductive metal or an electrically conductive metal alloy. Examples of electrically conductive metals include, but are not limited to, W, Cu, Al, Co, Ru, Ru, molybdenum (Mo), osmium (Os), or iridium (Ir). Examples of electrically conductive metal alloys include at least one of the electrically conductive metals mentioned above. An example of an electrically conductive metal alloy that can be employed in the present application includes, but is not limited to, Cu—Al. In some embodiments of the present application, the power element and the power via can be composed of a compositionally same electrically conductive material. In other embodiments of the present application, the power element and the power via can be composed of compositionally different electrically conductive materials.

Throughout the present application, the term “thermal via” denotes a via structure that transfers heat from a core unit of the first chip to a heat spreader element that is located in the second chip. The via structure that provides the thermal via of the present application is filled with one of the thermally conductive materials mentioned above for the heat spreader element. In some embodiments of the present application, the heat spreader element and the thermal via can be composed of a compositionally same thermal conductive material. In other embodiments of the present application, the heat spreader element and the thermal via can be composed of compositionally different thermal conductive materials.

Throughout the present application, the term “staggered manner” denotes one of the first chip or the second chip is positioned over the other of the first chip or the second chip in such a manner that each core unit of the second chip is located either under or over two adjacent core units of the first chip. That is, the staggering offsets the core units of the second chip from the core units of the first chip. Embodiments include when in which the second chip is located over the first chip, or when the second chip is located under the first chip.

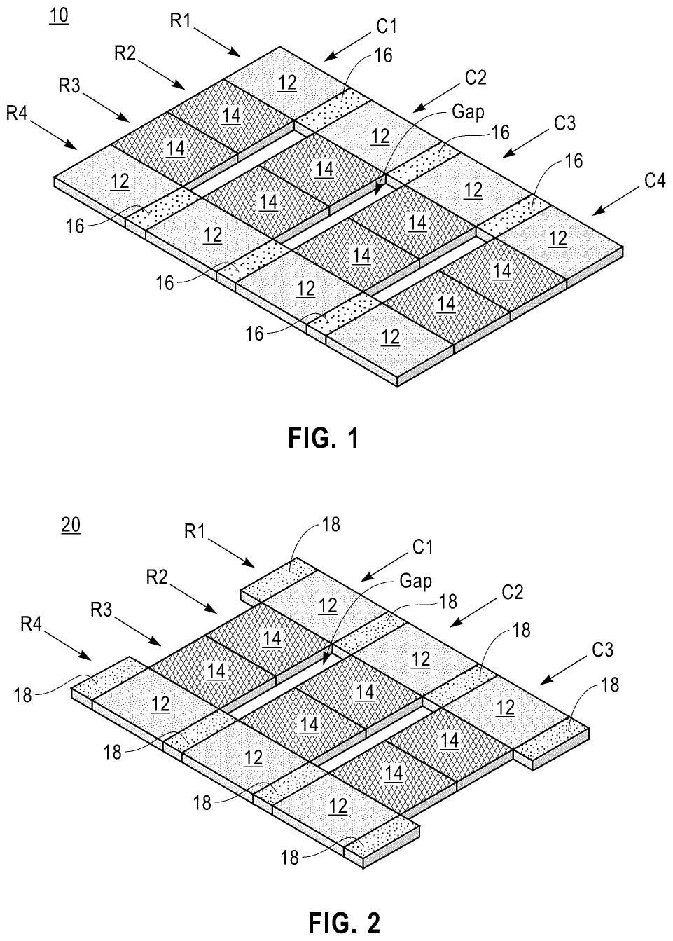

Referring now to FIG. 1, there is shown a first chip 10 (or first microprocessor) that can be employed in accordance with an embodiment of the present application. The first chip 10 includes a number of core units 12 and cache units 14 as shown in FIG. 1. In the present application, power from the first chip 10 can be delivered to the second chip 20 by means of using power vias 44 (as shown in FIG. 4); this aspect of the present application is described in more detail herein below. The first chip 10 is an independent unit with respect to the second chip 20. The first chip 10 can be independently tested. The first chip 10 can have size that is less than or greater than the second chip 20.

In the illustrated embodiment, the first chip 10 includes four rows, namely R1, R2, R3 and R4, and four columns, namely C1, C2, C3 and C4. Notably, the illustrated first chip 10 includes a first row R1 and a fourth row R4 of core units 12 that are spaced apart by a power element 16. First chip 10 also includes a second row R2 and a third row R3 of cache units 14. Each cache unit 14 within the second row R2 and the third row R3 of the first chip 10 is spaced apart by a gap. In the illustrated first chip 10, the cache units 14 of the first chip 10 in each column are in direct physical contact with each other. Although FIG. 1 illustrates a first chip 10 that is a 4×4 design (i.e., row×column design), the present application is not limited to a 4×4 design for the first chip 10. Instead, the present application contemplates using a 2N×2N design for the first chip 10 in which N is an integer starting from 1, and including 2, 3, 4, 5, etc. The first chip 10 can be formed utilizing semiconductor processing techniques that are well known to those skilled in the art.

Referring now to FIG. 2, there is shown a second chip 20 (or second microprocessor) that can be employed in accordance with an embodiment of the present application. In the illustrated embodiment of the present application, the second chip 20 is designed to have less core units 12 and less cache units 14 than the first chip 10. In other embodiments, the second chip 20 is designed to have greater core units 12 and greater cache units 14 than the first chip 10. In the present application, power from the first chip 10 can be delivered to the second chip 20 by means of using power vias. In the illustrated embodiment of the present application, the second chip 20 includes heat spreader elements 18 located at opposing edges of each of the core units 12 which can be used to cool the second chip 20 as well as the first chip 10; cooling of the first chip 10 is achieved by means of thermal vias 42 (as shown in FIG. 4) which transfer the heat generated by the core units 12 of the first chip 10 into the thermal spreader elements 18 of the second chip 20. It is noted that the present application is not limited to include heat spreader elements 18 located on opposing edges (ends) of each of the core units 12 of the second chip 20. Instead, the present application works when heat spreader elements 18 are located on a specific core unit 12 of the second chip 20. The second chip 20 is an independent unit with respect to the first chip 20. The second chip 10 can be independently tested.

In the illustrated embodiment, the second chip 20 includes four rows, namely R1, R2, R3 and R4, and three columns, namely C1, C2 and C3. Notably, the illustrated second chip 20 includes a first row R1 and a fourth row R4 of core units 12 that are spaced apart by a heat spreader element 18. Second chip 20 also includes a second row R2 and a third row R3 of cache units 14. Each cache unit 14 within the second row R2 and the third row R3 of the second chip 20 is spaced apart by a gap. In the illustrated second chip 20, the cache units 14 of the second chip 20 in each column are in direct physical contact with each other. Although FIG. 2 illustrates a second chip 20 that is a 4×3 design, the present application is not limited to a 4×3design for the second chip 20. Instead, the present application contemplates using a 2N×2N-1 design in which Nis as defined above; note that the second chip includes one less column than the first chip 10. In some embodiments, the second chip 20 can have a 2N×2N design and the first chip 10 can have a 2N×2N-1 design. The second chip 20 can be formed utilizing semiconductor processing techniques that are well known to those skilled in the art.

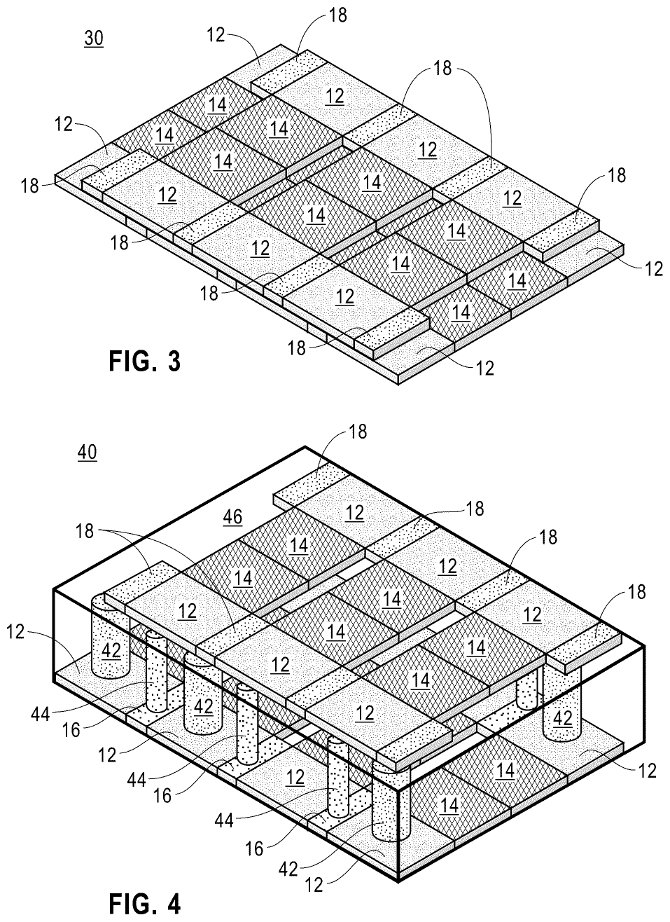

Referring now to FIG. 3, there is shown a 3D chip stack structure 30 in which the second chip 20 of FIG. 2 is stacked in a staggered manner over the first chip 10 of FIG. 1. FIG. 3 represents a simplistic view of a 3D chip stack structure (bonding or thermal and power vias not shown) in accordance with the present application. This simplistic view does not include the power vias and thermal vias mentioned above. FIG. 4 shows a 3D chip stack structure 40 in which the second chip 20 of FIG. 2 is stacked in a staggered manner over the first chip 10 of FIG. 1 and including power vias 44 and thermal vias 42. FIGS. 3 and 4 represent embodiments illustrating front-to-back-stacking. In the front-to-back-stacking embodiment illustrated in FIGS. 3 and 4, the frontside of the first chip 10 faces the backside of the second chip 20 and the power vias 44 and the thermal vias 42 provide a connection from the frontside of the first chip 10 to the backside of the second chip 20.

In some embodiments (not shown but readily discernable from FIG. 4), the frontside of the second chip 20 can face the backside of the first chip 10 and the power vias 44 and the thermal vias 42 provide connection of the frontside of the second chip 20 to the backside of the first chip 10.

In still other embodiments (not shown but readily discernable from FIG. 4), front-to-front stacking or back-to-back stacking can be employed. In the front-to-front stacking embodiment, the frontside of the first chip 10 faces the frontside of the second chip 20 and the power vias 44 and the thermal vias 42 provide connection of the frontside of the first chip 10 to the frontside of the second chip 20. In the back-to-back stacking embodiment, the backside of the first chip 10 faces the backside of the second chip 20 and the power vias 44 and the thermal vias 42 provide connection of the backside of the first chip 10 to the backside of the second chip 20.

As is illustrated in FIG. 4, the 3D chip structure of the present application can be encased in dielectric material structure 46. The dielectric material structure 46 provides electrically illustration to the 3D chip stack structure. Dielectric material structure 46 can include one or more dielectric layers that are composed of a material such as, for example, silicon oxide, silicon nitride, undoped silicate glass (USG), fluorosilicate glass (FSG), borophosphosilicate glass (BPSG), a spin-on low-k dielectric layer, a chemical vapor deposition (CVD) low-k dielectric layer, or any combination thereof. The term “low-k” as used throughout the present application denotes a dielectric material that has a dielectric constant of less than 4.0 (all dielectric constants mentioned herein are relative to a vacuum unless otherwise noted. In some embodiments, the dielectric material structure 46 can include one or more air gaps.

In the illustrated embodiment, the stacking includes positioning the second chip 20 over the first chip 10 in a staggered manner as defined above. Prior to this positioning, the power vias 44 and the thermal vias 42 are formed within one of the dielectric layers of the dielectric material structure 46. The power vias 44 and the thermal vias 42 can be formed utilizing a damascene process or subtractive patterning process, both of which are well known to those skilled in the art. Bond pads (not shown) can be formed on top of the power vias 44 and thermal vias 42. As mentioned above, the thermal vias 42 is formed on a core unit 12 of the first chip 10. The number of thermal vias 42 that are formed can vary. As mentioned above, the power vias 44 is formed on a power element 16 that is located between adjacent core units 12 of the first chip 10. After the positioning step, the second chip 20 is bonded to the dielectric layer including the power vias 44 and the thermal vias 42. Bonding can include a thermal bonding process or any other type of bonding process. Bond pads (not shown) can be positioned on the second chip 20 and aligned with the bond pads present on the power vias 42 and thermal vias 44.

Referring back to FIG. 4, there is illustrated a 3D chip stack in accordance with the present application. Notably, the 3D chip stack illustrated in FIG. 4 includes first chip 10 including a first number of core units 12 and a first number of cache units 14, and having power elements 16 located between each neighboring core unit 12 of the first chip 10. The 3D chip stack also includes second chip 20 including a second number of core units 12 and a second number of cache units 14, and having a heat spreader element 18 located on at least one of the core units 12 of the second chip 20. In the illustrated embodiment, the heat spreader element 18 is located on opposing ends of each core unit 12 of the second chip 20. In the present application, the heat spreader element 18 is placed with reference to thermal spots on the first chip 10 and connected to a bottom surface where the thermal spot are prominent by the thermal vias 42.

In the present application, the first chip 10 and the second chip 20 are stacked one on top the other in a staggered manner. In the illustrated embodiment, the second number is less than the first number. In other embodiments, the second number is greater than the first number. The staggered orientation of the first chip 10 and the second chip 20 reduces and confines power/thermal management points. The 3D chip stack of the present application further includes power via 44 connecting one of the power elements 18 of the first chip 10 to one of the core units 12 of the second chip 20, and thermal via 42 connecting one of the core units 12 of the first chip 10 to one of the heat spreader elements 18 of the second chip 20.

The presence of the power via 44 allows for power delivery from the first chip 10 to the second chip 20. Since the power via 44 is connected to one of the power elements 18 of the first chip 10, the impact of the power via 44 on the core units 12 and cache units 14 of the first chip 10 are reduced and sometimes even eliminated. This enables a more efficient design layout for performance-critical logic. The presence of the thermal vias 42 allows for heat dissipation from the core units 12 of the first chip 10 to the heat spreader elements 18 of the second chip 20. The thermal via 42 and thermal spreader element 18 eliminate hotspot stacking the inhibits traditional 3D chip stacking. Also, the staggered 3D chip stack illustrated in FIG. 4 provides performance and density improvements compared to conventional 3D chip stacking.

In some embodiments of the present application, the first chip 10 is located beneath the second chip 20. In such a stacked configuration it is possible to have (a) a frontside of the first chip 10 facing a frontside of the second chip 20, (b) a backside of the first chip 10 facing a backside of the second chip 20, (c) a frontside of the first chip 10 facing a backside of the second chip 20, and (d).a backside of the first chip 10 facing a frontside of the second chip 20.

In some embodiments of the present application, the first chip 10 is located above the second chip 20. In such a stacked configuration it is possible to have (a) a frontside of the first chip 10 facing a frontside of the second chip 20, (b) a backside of the first chip 10 facing a backside of the second chip 20, (c) a frontside of the first chip 10 facing a backside of the second chip 20, and (d).a backside of the first chip 10 facing a frontside of the second chip 20.

In some embodiments of the present application, dielectric material structure 46 is present that encases the first chip 10, the second chip 20, the power via 44 and the thermal via 42. The dielectric material structure 46 provides electrically isolation within the 3D chip stacked structure.

In embodiments of the present application, the first number is different from (i.e., greater than or less than) the second number.

In embodiments of the present application, the first chip has a size that differs from (i.e., greater than or less than) a size of the second chip.

In embodiments of the present application, a gap is located between each cache unit 14 within a row of caches units of both the first chip 10 and the second chip 20.

In embodiments of the present application, each core unit 12 of the second chip 20 lies between a pair of neighboring cache units 14 of the first chip 10.

Again referring back to FIG. 4, the illustrated 3D chip stack includes first chip 10 including a first number of core units 12 and a first number of cache units 14, and having power elements 16 located between each neighboring core unit 12 of the first chip 10. The 3D chip stack also includes second chip 20 including a second number of core units 12 and a second number of cache units 14, and having a heat spreader element 18 located on at least one of the core units 12 of the second chip 20; in the illustrated embodiment the heat spreader element 18 is located on opposing ends of each of the core units 12 of the second chip 20. In the present application, the first chip 10 and the second chip 20 are stacked one on top the other in a staggered manner. The staggered orientation of the first chip 10 and the second chip 20 reduces and confines power/thermal management points. As is shown, the core units 12 of the first chip 10 are located on the periphery of the first chip 10, and the core units 12 of the second chip 20 are located on the periphery of the second chip 20. This aspect of the present application limits the need for forming the power vias 44 and the thermal vias 42 with functional areas of the first and second chips. The 3D chip stack further includes power via 44 connecting one of the power elements 18 of the first chip 10 to one of the core units 12 of the second chip 20, and thermal via 42 connecting one of the core units 12 of the first chip 10 to one of the heat spreader elements 18 of the second chip 20.

The presence of the power via 44 allows for power delivery from the first chip 10 to the second chip 20. Since the power via 44 is connected to one of the power elements 18 of the first chip 10, the impact of the power via 44 on the core units 12 and cache units 14 of the first chip 10 are reduced and sometimes even eliminated. This enables a more efficient design layout for performance-critical logic. The presence of the thermal vias allows for heat dissipation from the core units 12 of the first chip 10 to the heat spreader elements 18 of the second chip 20. The thermal via 42 and thermal spreader element 18 eliminate hotspot stacking the inhibits traditional 3D chip stacking. Also, the staggered 3D chip stack illustrated in FIG. 4 provides performance and density improvements compared to conventional 3D chip stacking.

In some embodiments, in which the core units 12 of the first chip 10 are located on the periphery of the first chip 10, and the core units 12 of the second chip 20 are located on the periphery of the second chip 20, the first chip 10 is located beneath the second chip 20.

In some embodiments, in which the core units 12 of the first chip 10 are located on the periphery of the first chip 10, and the core units 12 of the second chip 20 are located on the periphery of the second chip 20, the first chip 10 is located above the second chip 20.

In some embodiments, in which the core units 12 of the first chip 10 are located on the periphery of the first chip 10, and the core units 12 of the second chip 20 are located on the periphery of the second chip 20, the structure can further include dielectric material structure 46 encasing the first chip 10, the second chip 20, the power via 44 and the thermal via 42. The dielectric material structure 46 provides electrical isolation within the structure.

While the present application has been particularly shown and described with respect to preferred embodiments thereof, it will be understood by those skilled in the art that the foregoing and other changes in forms and details may be made without departing from the spirit and scope of the present application. It is therefore intended that the present application not be limited to the exact forms and details described and illustrated, but fall within the scope of the appended claims.

What is claimed is:

1. A 3D chip stack structure comprising:
a first chip comprising a first number of core units and a first number of cache units, and having power elements located between each neighboring core unit of the first chip;
a second chip comprising a second number of core unit and a second number of cache units, and having a heat spreader element located on at least one of the core units of the second chip, wherein the first chip and the second chip are stacked one on top the other in a staggered manner;
a power via connecting one of the power elements of the first chip to one of the core units of the second chip; and
a thermal via connecting one of the core units of the first chip to one of the heat spreader elements of the second chip.

2. The 3D chip stack structure of claim 1, wherein the first chip is located beneath the second chip.

3. The 3D chip stack structure of claim 2, wherein a frontside of the first chip faces a frontside of the second chip.

4. The 3D chip stack structure of claim 2, wherein a backside of the first chip faces a backside of the second chip.

5. The 3D chip stack structure of claim 2, wherein a frontside of the first chip faces a backside of the second chip.

6. The 3D chip stack structure of claim 2, wherein a backside of the first chip faces a frontside of the second chip.

7. The 3D chip stack structure of claim 1, wherein the first chip is located above the second chip.

8. The 3D chip stack structure of claim 7, wherein a frontside of the first chip faces a frontside of the second chip.

9. The 3D chip stack structure of claim 7, wherein a backside of the first chip faces a backside of the second chip.

10. The 3D chip stack structure of claim 7, wherein a frontside of the first chip faces a backside of the second chip.

11. The 3D chip stack structure of claim 7, wherein a backside of the first chip faces a frontside of the second chip.

12. The 3D chip stack structure of claim 1, further comprising a dielectric material structure encasing the first chip, the second chip, the power via and the thermal via.

13. The 3D chip stack structure of claim 1, wherein the first number is different from the second number.

14. The 3D chip stack structure of claim 1, wherein the first chip has a size that is different from a size of the second chip.

15. The 3D chip stack structure of claim 1, further comprising a gap between each cache unit within a row of caches units of both the first chip and the second chip.

16. The 3D chip stack structure of claim 1, wherein each core unit of the second chip lies between a pair of neighboring cache units of the first chip.

17. A 3D chip stack structure comprising:
a first chip comprising a first number of core units and a first number of cache units, and having power elements located between each neighboring core unit of the first chip;
a second chip comprising a second number of core unit and a second number of cache units, and having a heat spreader element located on at least one of the core units of the second chip, wherein the first chip and the second chip are stacked one on top the other in a staggered manner, and the core units of the first chip are located on the periphery of the first chip, and the core units of the second chip are located on the periphery of the second chip;
a power via connecting one of the power elements of the first chip to one of the core units of the second chip; and
a thermal via connecting one of the core units of the first chip to one of the heat spreader elements of the second chip.

18. The 3D chip stack structure of claim 17, wherein the first chip is located beneath the second chip.

19. The 3D chip stack structure of claim 17, wherein the first chip is located above the second chip.

20. The 3D chip stack structure of claim 1, further comprising a dielectric material structure encasing the first chip, the second chip, the power via and the thermal via.
